(19) United States
(12) Patent Application Publication
(10) Pub. No.: US 2022/0268839 A1
(43) Pub. Date: Aug. 25, 2022

(54) TEST AND MEASUREMENT SYSTEM

(71) Applicant: Tektronix, Inc., Beaverton, OR (US)

(72) Inventors: John J. Pickerd, Hillsboro, OR (US); Keith D. Rule, Beaverton, OR (US); Mark Anderson Smith, Portland, OR (US)

(21) Appl. No.: 17/681,617

(22) Filed: Feb. 25, 2022

Related U.S. Application Data
(60) Provisional application No. 63/153,933, filed on Feb. 25, 2021.

(51) Int. Cl. G01R 31/3183; G01R 31/317; G01R 31/319

(52) U.S. Cl. CPC G01R 31/318314; G01R 31/31835; G01R 31/31726; G01R 31/31919

(57) ABSTRACT

A test and measurement system includes a primary instrument having an input for receiving a test signal for measurement or analysis from a Device Under Test (DUT) and generating a test waveform from the test signal, and a duplicator for sending a copy of the test waveform to one or more secondary instruments. The one or more secondary instruments are each structured to access the copy of the test signal for analysis, and each of the one or more secondary instruments includes a receiver structured to receive a command related to measurement or analysis of the copy of the test waveform, one or more processes for executing the received command, and an output for sending results of the executed command to be displayed on a user interface that is separate from any user interface of the one or more secondary instruments.

### CROSS-REFERENCE TO RELATED APPLICATIONS

This disclosure is a non-provisional of and claims benefit from U.S. Provisional Patent Application 63/153,933, titled “TEST AND MEASUREMENT SYSTEM,” filed Feb. 25, 2021, the disclosure of which is incorporated herein by reference in its entirety.

### TECHNICAL FIELD

This disclosure relates to test and measurement systems, and more particularly to test and measurement systems that operate in a parallel fashion.

### BACKGROUND

An automated test system including a test and measurement instrument, such as an oscilloscope (“scope”), often cannot compute measurements fast enough for the needs of the user. Some measurements require significant processing time. This is a significant problem in environments such as manufacturing test, where reduction of test time and maximization of throughput are important objectives. Some have proposed parallel/pipeline waveform processing in a cloud computing environment or additional PCs or other processing devices. But, there is presently no way to coordinate and operate multiple test devices that each run independently. This problem grows with the increasing precision and speed of modern test and measurement equipment, which include input signal sampling rates up to billions or trillions of times per second.

Embodiments of this disclosure address these and other deficiencies in the state of the art.

### BRIEF DESCRIPTION OF THE DRAWINGS

FIG. 1 is a functional block diagram of an example test and measurement system including a primary instrument and one or more secondary instruments, according to embodiments.

FIG. 2 is a functional block diagram of an example master test controller component of the test and measurement system of FIG. 1, according to embodiments.

FIG. 3 is a functional block diagram of an example primary test instrument component of the test and measurement system of FIG. 1, according to embodiments.

FIG. 4 is a functional block diagram of an example secondary test instrument component of the test and measurement system of FIG. 1, according to embodiments.

FIG. 5 is a functional block diagram of another example secondary test instrument component of the test and measurement system of FIG. 1, according to embodiments.

FIG. 6 is a diagram of an example user interface that may be used to control components of the test and measurement system of FIG. 1, according to embodiments.

### DESCRIPTION

Embodiments of the disclosure generally include a test system architecture for improving the speed of an automated test system.

In general, the test and measurement system described herein includes a primary instrument for acquiring a test signal from a Device Under Test (DUT), and one or more secondary instruments that perform various measurements on the acquired test signal. If present, a master test controller, as described below, drives coordination between all of the devices in the test system, and provides a display that simultaneously presents the output of all of the devices in a single display. If the master controller is not present, the primary instrument may include the functionality to drive the testing system. Further, a user interface allows the user to control any or all of the coupled devices from a single control panel.

Although this disclosure describes an embodiment of the architecture that includes one or more oscilloscopes as the primary test and measurement instrument, one of ordinary skill in the art will recognize that embodiments according to the disclosure may include and/or be used with many other types of signal analysis instruments, in addition to oscilloscopes, that require significant measurement computation and/or processing time.

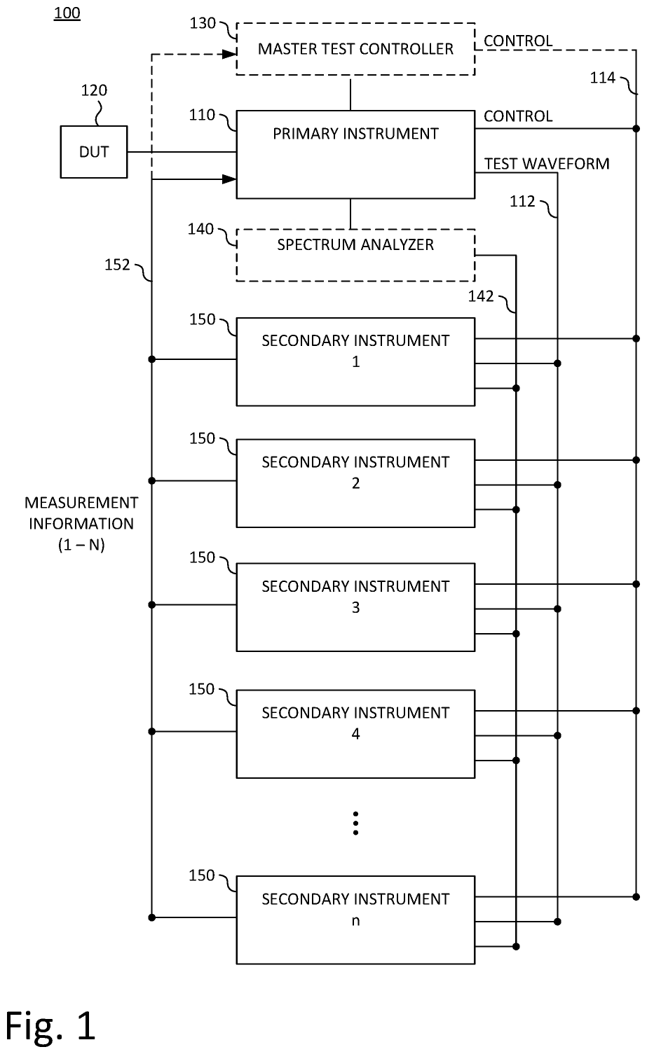

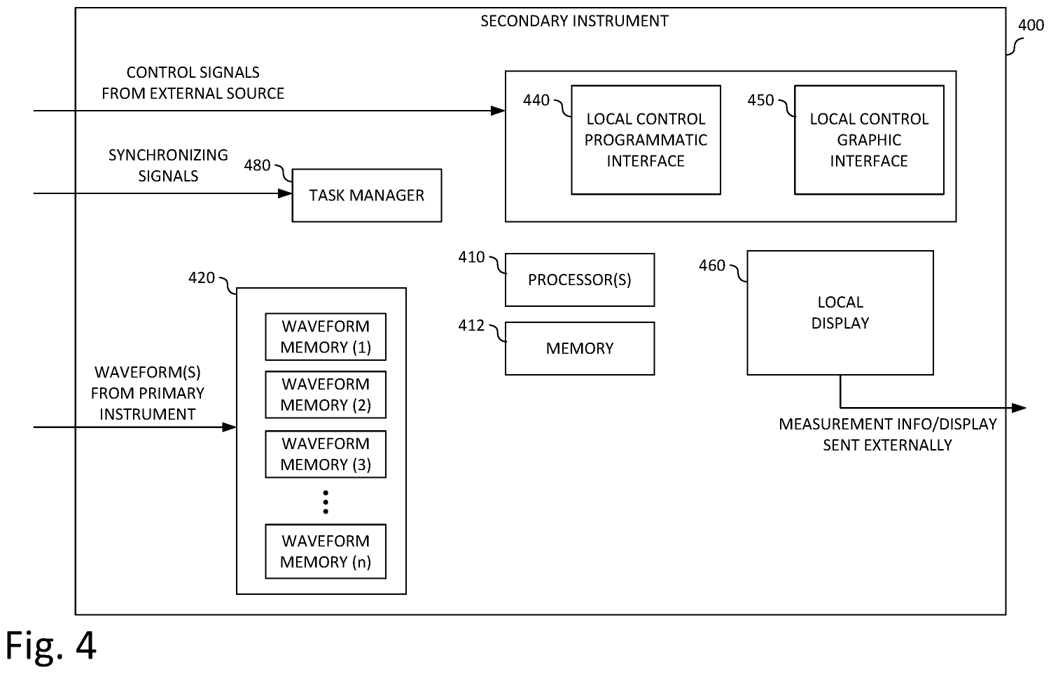

FIG. 1 is a functional block diagram of an example test and measurement system 100 including a primary instrument 110 and one or more secondary instruments 150, according to embodiments. The primary instrument 110 is an oscilloscope, or other measurement device that acquires signals from a Device Under Test (DUT) 120. The DUT 120 typically generates electrical signals that are being tested, but the DUT may generate optical signals as well. A test signal is received from the DUT 120 by the primary instrument 110. The test signal is ingested by the primary instrument 110 in a typical fashion, which may include filtering, such as de-embedding filtering, down-conversion, sampling, and analog-to-digital conversion, or other processing to produce what will be referred to herein as a test waveform. The test waveform is copied or otherwise sent to one or more secondary instruments 150 through a signal line 112. The signal line 112 may be a single line that sends data in serial fashion, or the signal line may be a parallel line that sends multiple signals at once. The primary instrument 110 may include multiple input channels, and different test signals may be simultaneously acquired as different test waveforms on each input channel. Each acquired test waveform may be selectively routed to one or more of the secondary instruments 150. There may be any number of secondary instruments 150, which in FIG. 1 are labeled as instruments 1-n. Additional details of the secondary instruments are described with reference to FIG. 4 below.

The primary instrument 110 may also send control signals to the secondary instruments 150 through a control line 114. In some embodiments, such as the ones described below, a master test controller 130 is primarily responsible for sending the control signals on the control line 114. In other embodiments both the master test controller 130 and the primary instrument 110 may send the control signals. In any case, the control signals carried on the control line 114 control the operation of the secondary instruments 150. Further description herein describes the control signals coming from the master test controller 130, although embodiments of the invention are not required to use the master test controller, and instead such functionality may be performed by the primary instrument 110. In some embodiments, the master test controller 130 may be implemented as software running on the primary instrument 110, or on other hardware. Also, although only a single primary instrument 110 is illustrated in FIG. 1, embodiments of the invention may include more than one primary instrument to receive test signals from the DUT 120 to be routed to the various secondary instruments 150.

In some embodiments, one or more additional instruments, different from the primary instrument 110 and the secondary instruments 150, may be used in the system. The example test system 100 of FIG. 1 includes a spectrum analyzer 140, which may be an example of such an additional instrument. Output from the additional instrument may be also sent to the secondary instruments 150, such as on another connection line 142 or on the signal line 112. In other embodiments the additional instrument does not send its output to the secondary instruments, and may communicate only with the primary instrument 110 or, if present, the master test controller 130.

In general, the user will set up the various secondary instruments 150 to each perform different measurements or perform other analysis on the test waveforms. Then, output from the secondary instruments 150 is sent back to the master test controller 130, or even to the primary instrument 110, where it is viewed on a user interface that shows the output from each of the secondary instruments 150, as described and illustrated below.

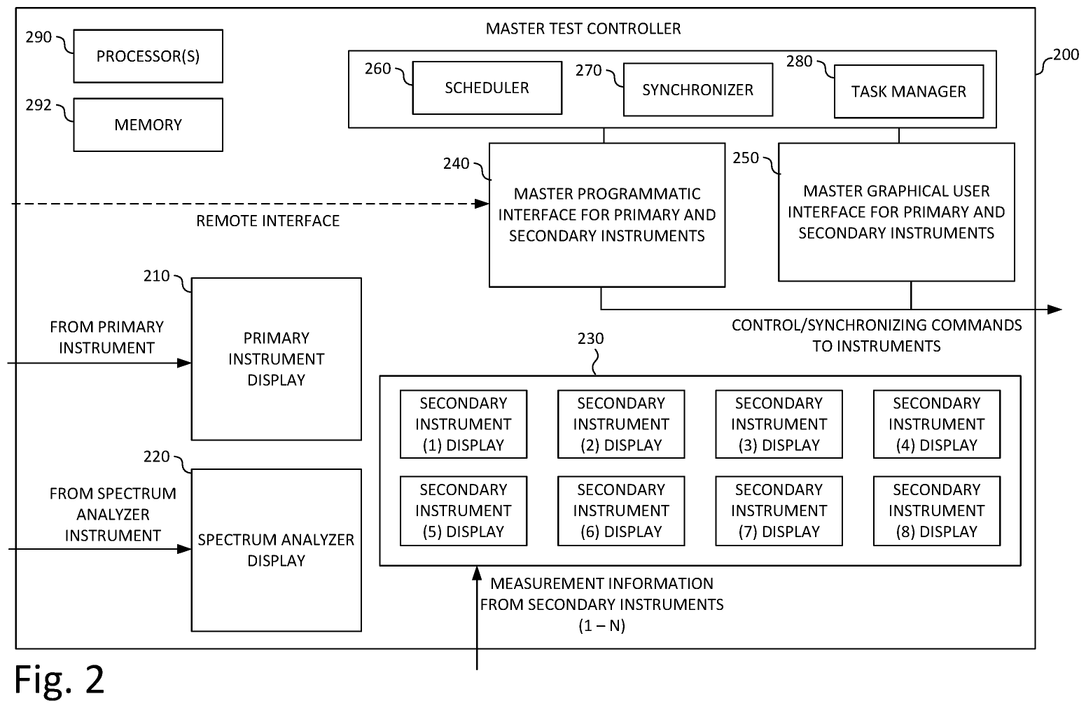

FIG. 2 is a functional block diagram of an example master test controller 200 of the test and measurement system of FIG. 1, according to embodiments. The master test controller 200 may be an example of the master test controller 130 described with reference to FIG. 1.

The master test controller 200 itself may operate on a specific hardware device, such as a computer. The computer includes one or more processors 290, as well as memory 292 used to store one or more programs to operate the master test controller 200. The memory 292 may additionally store data or other information relevant to the master test controller 200.

The master controller 200 may include multiple displays for viewing outputs from the various devices in the test and measurement system 100 of FIG. 1. For instance, a display 210 shows output generated by the primary instrument 110 FIG. 1, while a display 220 shows output generated by the spectrum analyzer 140 of FIG. 1. Further, an array 230 of displays shows outputs from all of the secondary instruments 150 of FIG. 1, each in its own window of the array 230. As each of the secondary instruments 150 performs separate measurements on the test waveform that was routed to the instrument, the output from each of the secondary instruments may generate different outputs, each directed to the specific measurement being performed by the particular secondary instrument. For example secondary instrument 1 may measure voltage of the test waveform, while secondary instrument 2 may measure current. Other secondary instruments 150 may monitor various threshold levels and produce output only when such thresholds are exceeded. Other secondary instruments 150 may be configured to perform yet other analysis or measurement, such as bit error rate testing or eye closure testing, or other operations on the test waveform. Embodiments of the invention allow all of the outputs of the secondary instruments to be viewed simultaneously. Further, as described in detail below, each of the secondary instruments 150 may be controlled to be operating on the same portion of the same test waveform, simultaneously. In this way the user may gain the benefit of analyzing different and various measurements of the waveform by watching what happens in all of the secondary instruments 150, simultaneously.

Control and setup of the various primary and secondary instruments is performed through interfaces 240, 250, of the master test controller 200. The interfaces 240, 250 of the test controller 200 of FIG. 2 are illustrated as separate interfaces, for clarity, although these interfaces may be combined into a single interface. In general, the interface 240 is a programmatic interface that allows the user to input programming commands, such as setup and run commands to one or more of the primary instrument 110 and secondary instruments 150. The programmatic interface 240 may be used to send individual commands to any of the primary instrument 110 and secondary instruments 150. For instance the user may use the programmatic interface 240 to set up the secondary instrument 150 (1) to measure voltage of the test waveform, and also set up the secondary instrument 150 (2) to measure current of the test waveform. Example commands may include any known test instrument commands, such as Programmatic Interface (PI) commands. Or, the user may develop his or her own commands for operating the primary instrument 110 and secondary instruments 150.

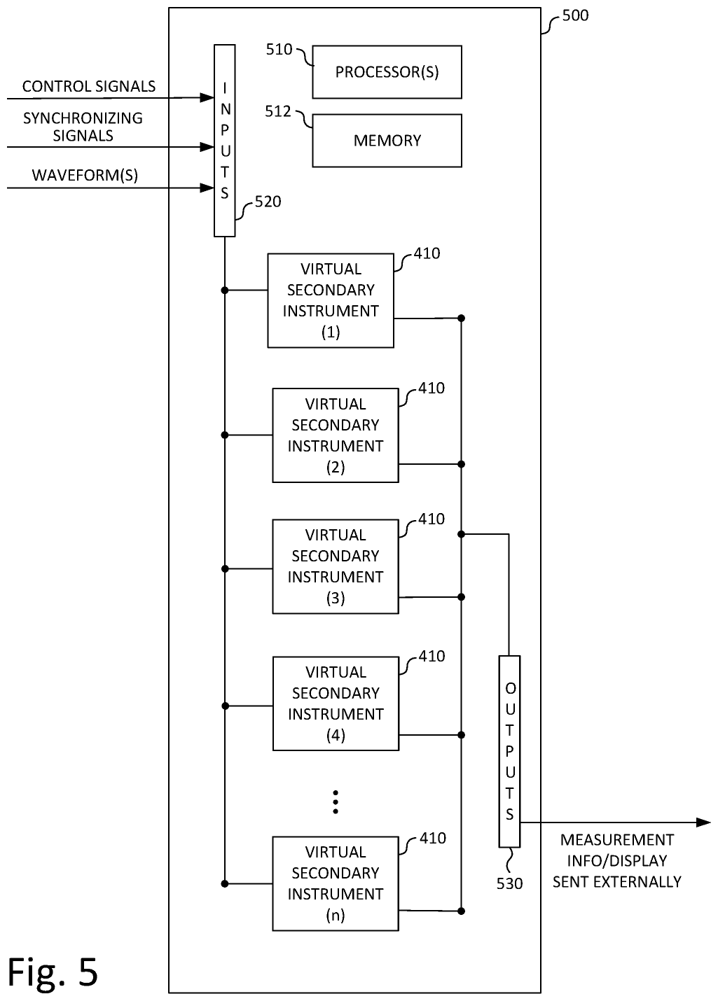

A graphical interface 250 may be used instead of, or in addition to, the programmatic interface 240. An example graphical interface is described with reference to FIG. 5, below.

Either or both of the programmatic interface 240 and graphical interface 250 may use various functions to control the operation of the test system 100. A scheduler 260 may be a collection of particular operations or functions that operate on the processor 290 to schedule operation of the test system 100. For example, the scheduler 260 may be used to set up and initiate particular operations of the secondary instruments 150. A synchronizer 270 may be used to ensure all the primary instrument 110 and secondary instruments 150 are operating on the same portion of the test waveform, so all of the output displays in the array 230 are synchronized to one another. The synchronizer 270 may send periodic signals to the secondary instruments 150 to keep them in alignment, for example. Or, the synchronizer 270 may specify that the testing of the test waveform is to begin at a particular portion of the test waveform, such as 15.3000 seconds. Then each of the connected instruments 110, 150, and any other instrument of the test system 100 sets its starting point for analysis at the exact specified time. When initiated by a start or run command, all of the secondary instruments operate on their local copy of the test waveform and produce their individual test results, which are then sent back to the master controller 200 for viewing on the array 230 of displays. The synchronizer 270 may send signals periodically to the primary instrument 110 and secondary instruments 150 during the testing to ensure each instrument continues to operate synchronously.

In some embodiments the synchronizer 270 is used to implement a debug feature, where each of the secondary instruments 150 operate for a specified or pre-determined time and then simultaneously stop operating and are placed in a wait state, while the operator analyzes the output of the secondary instruments 150 in the array 230 of displays. Then, the operator may execute a command, such as by pressing a ‘step’ button on the master test controller 130, to cause the primary instrument 110 and all the secondary instruments 150 to proceed again, for the specified time, and again enter a wait state. The specified time may be very short, measured in fractions of a second. In other embodiments the next debug state is determined by features of the waveform itself, rather than being limited by time. In other embodiments the primary instrument 110 or master controller 200 may be configured to detect a triggering event at which time a ‘stop’ command is sent to all of the secondary instruments 150. This ensures the secondary instruments remain synchronized when they again start measuring the test waveform. Such fine time, event, and trigger control allows the user to evaluate many facets of the test waveform quickly and simultaneously by evaluating the output of all of the primary instrument 110 and secondary instruments 150 at the same time. The master test controller 130 generates the commands to control the simultaneous operation of all of the secondary instruments 150.

A task manager 280 may further be used by either or both the programmatic interface 240 and graphical interface 250 to coordinate various operations between and amongst the primary instrument 110 and secondary instruments 150, as described below.

The output of the programmatic interface 240 and/or graphical interface 250, and any or all of the scheduler 260, synchronizer 270, and task manager 280 is sent to the primary instrument 110 and secondary instruments 150 through the control line, such as the control line 114 of FIG. 1. The outputs may be directed to one or more individual of the secondary instruments 150 by individual address or identification, or the outputs may be directed to all of the selected secondary instruments 150 simultaneously.

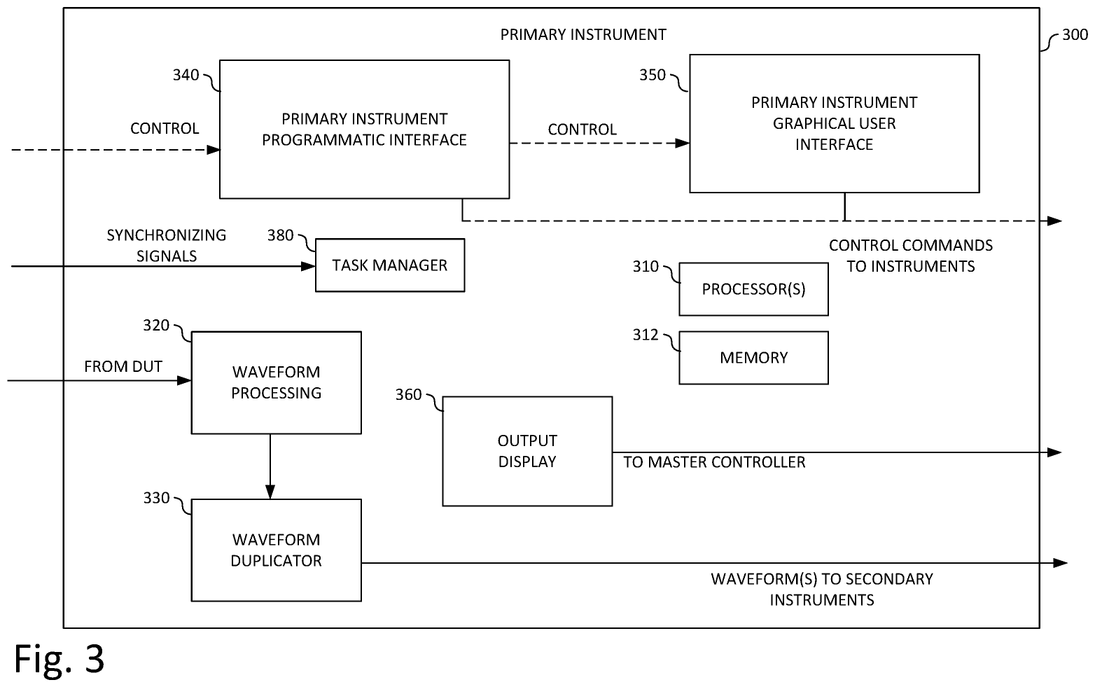

FIG. 3 is a functional block diagram of an example primary test instrument 300 component of the test and measurement system of FIG. 1, according to embodiments. Primary instrument 300 may be an example of the primary instrument 110 of FIG. 1. In general, the primary test instrument 300 may operate the same as, or similar to a conventional test instrument, such as an oscilloscope, with some additional functionality. As conventional test instruments are well known, such as the fact that they operate using one or more processors 310 and associated memory 312, discussion of typical instrument operation is omitted for brevity.

The primary test instrument 300 accepts an input signal from the DUT and may perform typical waveform processing in a waveform processor 320. Such processing may include generating samples from the input signal to create a waveform, filtering, extracting a clock signal, or converting the input signals from analog to digital signals, for instance. In other embodiments little or no processing is done to the input signal, and instead the signal is received and stored in its raw state. A waveform duplicator 330 selects a desired portion of the input signal and creates copies of the waveform to be sent to the secondary instruments 150 (FIG. 1). The waveform duplicator may create multiple copies, or may instead send a single copy to each of the secondary instruments 150. In any case, the primary instrument ensures that the desired portion of the input signal to be analyzed is sent to the secondary instruments 150. The primary test instrument 300 may accept input signals from the DUT on multiple channels and create multiple test waveforms. As described below, the primary test instrument 300 may route any particular of its stored waveforms to any of the secondary instruments 150. Thus, it is not necessary that each secondary instrument 150 operates on an identical waveform. But, in general, all of the test waveforms of all of the secondary instruments 150 are related to one another, in that all of the input signals from the various channels of the primary instrument 300 are related to one another by time, as they are acquired at the same time.

The primary instrument 300 may include a programmatic interface 340 and/or a graphical user interface 350, through which the user may set up and operate the primary instrument. In embodiments of the invention that do not include a separate master controller, such as the master test controller 130, all of the functionality described above with respect to the master controller may instead be performed by the primary instrument 300. In those embodiments that do include a master test controller 130, the primary instrument 300 may accept control signals from the master controller. The control signals may be received at either of the interfaces 340 or 350, for instance. Additionally, synchronization signals may be received from the master test controller 130 to a task manager 380, which may control the primary instrument 300 performing certain tasks, or may control the synchronization of the primary instrument so that it stays synchronous with the secondary instruments, as described above. Although illustrated separately, in some embodiments the control signals and synchronizing signals may be received by the primary instrument 300 through a single control line.

The primary instrument 300 further includes a local output display 360, which may be separate from the graphical user interface 350. In either case, a copy of the output display 360 is sent to the master test controller 130 for display on the primary instrument display of such controller, as described above with reference to FIG. 2. The output display 360 may show the raw waveform as it is being accepted from the DUT, or may show the state of the waveform as it is being acted on by the primary instrument 110, for example.

A main function of the primary instrument 300 is to accept the signal or signals from the DUT and produce a waveform for analysis. In some embodiments, only the functionality of accepting the test signal and producing copies of the waveform, or otherwise making them available to one or more secondary test instruments 150, is performed by the primary instrument 300. In this embodiment, instead of using the primary instrument 300 to accept the input signals, a signal receiver may accept the signal for analysis, make the signal available to other instruments in the system, but not perform any analysis or even generate local output of the waveform. In the signal receiver embodiment, the output display 360 as well as the interfaces 340 or 350, or both, may be omitted from the primary instrument 300. These functions may instead be performed by a Personal Computer (PC) that runs software capable of implementing such functions. In such an embodiment, the signal receiver is structured to gather the signals for testing, while the master controller, such as the master test controller 200 of FIG. 2 is used to distribute copies of the waveform to the secondary instruments 150 and to control the operation of the secondary instruments. Such an embodiment may be particularly useful in a manufacturing test application, allowing the primary instrument to be almost fully dedicated to receiving test signals from DUTs and acquiring test waveforms, while one or more secondary instruments may be selectively and dynamically employed to perform measurements or analysis of those waveforms, thereby increasing asset utilization of the primary instrument, increasing manufacturing test throughput, and decreasing overall test time.

FIG. 4 is a functional block diagram of an example secondary test instrument 400 of the test and measurement system of FIG. 1, according to embodiments. The secondary test instrument 400 may be an example of one of the secondary test instruments 150 of FIG. 1. A typical test system 100 includes multiple copies or instances of the secondary test instruments 400.

The secondary instrument 400 operates on a device controlled by one or more processors 410 and associated memory 412. In some embodiments, and differently than the primary instrument 400, the secondary instrument 400 lacks the ability to accept a test signal directly from a DUT. Such ability to receive a test signal typically includes specialized hardware, such as an input port and acquisition circuitry, and/or software, as described above with reference to the primary instrument 300. Since the secondary instrument 400 lacks this functionality, it can generally be produced much more inexpensively than the primary instrument 300. In some embodiments the secondary instrument 400 may be a completely virtual instrument that includes no specialized hardware at all, and may instead be operated by software running on a general purpose or special purpose processor. Such an example is illustrated with reference to FIG. 5 below. In some embodiments, the secondary instrument 400 may be an instance of a software application running on a computing device, which may be the same computing device on which the master test controller software is running. In some particular embodiments, the secondary instrument 400 may be an instance of TekScope® PC software. In other embodiments the secondary instrument 400 may be programmed into specially produced hardware, or a combination of hardware and software. The secondary test instrument 400 may operate as a virtual machine running on a computing device. In some embodiments, with enough computing resources, a single hardware device may operate multiple secondary test instruments 400 as their own, independent, virtual machines. In yet other embodiments the secondary test instrument 400 can operate in the cloud, i.e., on a device that communicates to a central system that provides computing resources from a remote source. In a typical environment, each copy of the secondary instrument 400 operates on its own separate hardware, such as a Personal Computer (PC), and there are multiple PCs each operating their own secondary instrument in the testing system.

The secondary instrument 400 includes an input for accepting one or more test waveforms from the primary instrument, such as the primary instrument 110 of FIG. 1. The waveforms are stored in a waveform storage 420. The waveform storage 420 may be configured to store a single waveform or multiple waveforms. The secondary instrument 400 may operate on one waveform stored in the waveform store 420, while it receives additional waveforms for later operation. In some embodiments the waveform presently being measured or analyzed by the secondary instrument 400 may be stored separate from the waveform storage 420, such as in the memory 412 or in another, specialized, memory.

The secondary instrument 400 may include a programmatic interface 440 and a graphic interface 450. In some embodiments only the programmatic interface 440 is present in the secondary instrument. The programmatic interface 440 and/or graphic interface, if present, receives program and control signals from an external source, such as from the primary instrument 100 and/or master test controller 130 of FIG. 1. These program and control signals allow the user for set up and control the operation of the secondary instrument 400. As described above, there may be multiple copies, or instances, of the secondary instrument 400 in the overall test system 100. In this way the user may expand the test system 100 to include any desired number of secondary instruments 400 to perform any desired tests or measurements of the test waveform.

Synchronizing signals may be received at a task manger 480. As described above with reference to the primary controller 300, the synchronization signals control synchronization of the primary instrument to each of the secondary instruments 400 so that they stay synchronous to the primary instrument 110 and all of the other secondary instruments in the test system 100. Also as described above, in some embodiments the control signals and synchronizing signals may be received by the secondary instrument 400 through a single control line.

In operation, the master test controller 130 controls all of the secondary instruments 400 in the test system 100 to perform measurements or other analysis on the test waveform at exactly the same time. Output of each of the secondary instruments 400 may be shown on a local display 460, or the output may be sent externally, to the master test controller 130. Example output may include specific waveforms or other output typically generated by test devices. Especially for secondary instruments 400 operating in locations remote from an operator, which embodiments of the invention easily allow, the local display 460 may be purposely turned off to speed operation of the secondary instrument. This action of turning off the local display 460 may save computing resources.

By including multiple secondary instruments 400 in the test system 100, embodiments of the invention enable waveform processing measurement acceleration using a parallel/pipelined process.

Embodiments of the invention provide multiple improvements over previous test and measurement systems. One improvement is that a unified menu control system, such as the programmatic interface 240 and graphical interface 250 of FIG. 2 makes it easy to program, and debug, and single step the entire system, in a manner that is not presently possible.

FIG. 5 illustrates an example of the embodiment described above where the functions of the secondary instrument 400 described above are virtualized as software processes or functions running on one or more hardware devices 500. In FIG. 5, the hardware device 500 receives the control signals, synchronizing signals and waveforms at an input 520 for all of one or more virtual secondary instruments 410, which may operate with the same functionality as the secondary instrument 400 described with reference to FIG. 4. The virtual secondary instruments 410 are each software replications of the functions described as being carried out by the secondary instrument 400 of FIG. 4, such as accepting the input waveform and performing measurement operations on the input as controlled by the control signals and synchronizing signals. Each of the virtual secondary instruments 410 may generate an output of the measurement information, which may include output display graphs, eye diagrams, or any output typically generated by a test and measurement instrument and sends it to an output 530, for further sending to a master test controller, such as the master test controller 130 of FIG. 1. Virtualizing the functions of the secondary instruments 400 as the virtualized secondary instruments 410 provides the functionality of the secondary instruments 400 without invoking additional hardware costs for each copy of each secondary instrument 400. Instead, virtualized secondary instruments 410 may be invoked as needed by adding more virtualized secondary instruments 410. The hardware device 500 includes one or more processors 510 and memory 512 to control the operation of the virtualized secondary instruments 410. The hardware device 500 may be implemented as a cloud-based processor, or local computing resources.

In some embodiments the test system 100 may include a mix of secondary instruments 400 and virtual secondary instruments 410. Reference herein to one or more secondary instruments 400 may also be interpreted as references made to one or more virtual secondary instruments 410, as the functionality of the secondary instruments 400, 410 may be the same no matter if they are hardware copies or virtualized copies.

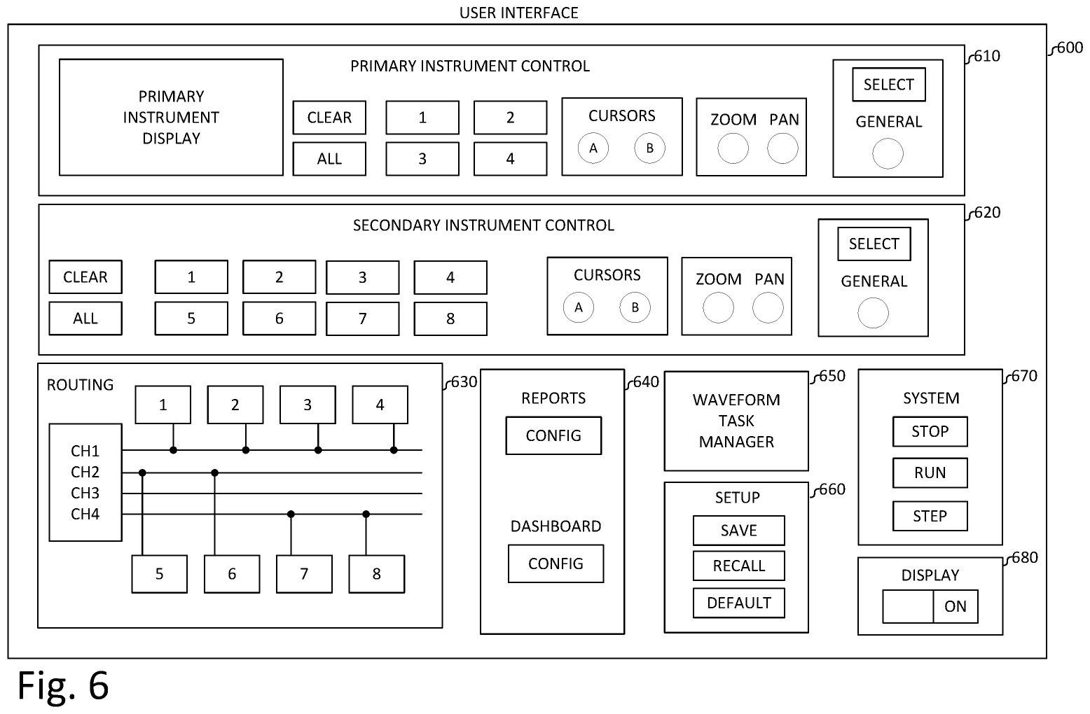

FIG. 6 is a diagram of an example user interface 600 that may be used to control components of the test and measurement system of FIG. 1. The user interface 600 may be an example of the graphical interface 250 of FIG. 2, although the user interface 600 is only one example of such a graphical interface 250.

The user interface 600 includes a primary instrument control panel 610 for controlling a primary instrument, such as the primary instrument 300 of FIG. 3. Remote interfaces for controlling primary instruments are known and will not be described in detail herein. In general, though, the primary instrument control panel 610 allows the user to control the operation of the primary instrument, such as by controlling operation of the device, controlling cursors, and allows control of the output generated by the primary instrument. The primary instrument control panel 610 may also include a small representation of the output of the primary instrument. Pan and zoom controls also allow the user to control how the output from the primary instrument is visualized.

The user interface 600 further includes a secondary instrument control panel 620 for controlling any or all of the secondary instruments, such as the secondary instrument 400 of FIG. 4 and/or virtual secondary instruments 410 of FIG. 5. Although FIG. 6 illustrates control for eight secondary instruments 400, 410 (1-8), any number of secondary instruments may be controlled through the secondary instrument control panel 620. Notably, the secondary instrument control panel 620 allows the user to select which of the secondary instruments 400, 410 (1-8) are to be controlled through the secondary instrument control panel 620. For example, the user may desire to only control pan and zoom for secondary instruments 1 and 3, while leaving the output displays for the remaining secondary instruments in their native state. Then, with reference to FIG. 2, only the secondary instrument displays for instruments 1 and 3 in the array 230 will be controlled by the user. In practice, when the user selects commands for only certain of the secondary instruments, then commands are generated and sent on the control line 114 (FIG. 1) for only the selected secondary instruments.

A routing section 630 provides the user with an ability to connect the secondary instruments 400, 410 to any of the input channels of the primary instrument 300, as described above. Typically, a primary instrument 300 includes multiple input channels, which may be connected to different inputs from the DUT. With reference to FIG. 6, secondary instruments 400, 410 numbers 1-4 are connected to channel 1, while secondary instrument numbers 5 and 6 are connected to channel 2 of the primary instrument. Secondary instrument numbers 7 and 8 are coupled to channel 4, and no secondary instrument 400, 410 is coupled to channel 3. Providing the ability to route various input channels to the various secondary instruments 400, 410 through a common interface provides the user with flexibility not previously possible. This routing section 630 allows the user to direct which actual waveform from the primary instrument 300 go to which secondary instrument 400, 410. As described in detail above, the same waveform from the primary instrument 300 can go to more than one secondary instrument 400, 410.

Other features of the user interface 600 include a setup panel 660, which allows the user to create, store, and recall setups that are used often. This alleviates the necessity to set up the system individually for each testing sequence. A panel 680 allows the user to selectively turn on or off the displays for any or all of the secondary instruments 400. Various reports may be configured through a configuration panel 640. Further, the user may configure a dashboard, such as illustrated in FIG. 2, using the configuration panel 640. The waveform task manager 650 allows the user to specify various tasks to be operated on by the secondary instruments 400, 410. Tasks may include any of the operations that are described herein, and further include any operation typical for test and measurement devices. Finally, a system control panel 670 provides the user with the ability to start and stop the testing of any of the primary instrument 300 and secondary instruments 400. Further, the system control panel 670 allows the user to operate the debug mode described above, by causing each of the selected secondary instruments 400, 410 to step through the test waveform in small time increments or based on events or triggers in the test waveform.

Linked menus, such as the user interface 600, allows the user to view and set up all of the secondary instruments simultaneously by operating only a single control, which speeds the initial programming of the test system 100, rather than setting up all of the devices individually.

Other advantages of embodiments of the invention include being able to operate with test instruments from different manufacturers. For example, the primary instrument 300 may be one manufacture's product, while the secondary instruments 400, 410 may be produced from another manufacturer. Flexibility in the programming and control of the connected components allows for such interoperability.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the disclosed technologies are provided below. An embodiment of the technologies may include one or more, and any combination of, the examples described below.

Example 1 is a test and measurement system including a primary instrument having an input for receiving a test signal for measurement or analysis from a Device Under Test (DUT) and generating a test waveform from the test signal, and a duplicator for sending a copy of the test waveform to one or more secondary instruments. The one or more secondary instruments are each structured to access the copy of the test waveform for analysis, and each of the one or more secondary instruments includes a receiver structured to receive a command related to measurement or analysis of the copy of the test waveform one or more processes for executing the received command, and an output for sending results of the executed command to be displayed on a user interface that is separate from any user interface of the one or more secondary instruments.

Example 2 is a test and measurement system according to Example 1, further comprising a master controller coupled to the output of the one or more secondary instruments, and the master controller having a user interface with a window to display the output of each of the one or more secondary instruments.

Example 3 is a test and measurement system according to any of the previous Examples, in which the user interface of the master controller further includes an input for controlling the primary instrument and selected ones of the one or more secondary instruments.

Example 4 is a test and measurement system according to any of the previous Examples, in which in which each of the one or more secondary instruments is structured to execute its received command substantially simultaneously.

Example 5 is a test and measurement system according to any of the previous Examples, in which in which the test waveform includes multiple segments, and in which each of the one or more secondary instruments is structured to operate on the same of the multiple segments substantially simultaneously.

Example 6 is a test and measurement system according to any of the previous Examples, in which in which the master controller is structured to send synchronization information to the one or more secondary instruments.

Example 7 is a test and measurement system according to any of the previous Examples, in which in which at least one of the one or more secondary instruments operate as a virtual computer process.

Example 8 is a test and measurement system according to any of the previous Examples, in which, in which each of the one or more secondary instruments lacks any input for receiving the test signal from the DUT.

Example 9 is a test and measurement system according to any of the previous Examples, in which, in which each of the one or more secondary instruments is structured to, after receiving a stop command, stop execution and remain in a wait state.

Example 10 is a test and measurement system according to Example 9, in which each of the one or more secondary instruments is structured to simultaneously restart execution upon receipt of another command.

Example 11 is a test and measurement system according to Example 9, in which each of the one or more secondary instruments is structured to execute for a pre-defined time prior to stopping execution.

Example 12 is a test and measurement system including a signal receiver in a primary instrument including an input for receiving a test signal for measurement or analysis from a Device Under Test (DUT) from which a test waveform is generated, a master controller coupled to the signal receiver and structured to make a copy of the test waveform available to one or more secondary instruments, in which the one or more secondary instruments each structured to access the copy of the test waveform for analysis, and each of the one or more secondary instruments includes a receiver structured to receive a command related to measurement or analysis of the copy of the test waveform from the master controller, one or more processes for executing the received command, and an output for sending results of the executed command to the master controller.

Example 13 is a test and measurement system according to Example 12, in which the master controller is structured to simultaneously display the output of each of the one or more secondary instruments.

Example 14 is a method of operating a test and measurement system, including receiving a test signal for measurement or analysis from a Device Under Test (DUT) at a first device, generating a test waveform from the test signal, selectively routing a copy of the test waveform to one or more test devices and, at the one or more test devices, receiving a command related to measurement or analysis of the copy of the test waveform, executing the received command, and sending an output of the executed command to a user interface that is separate from the one or more test devices.

Example 15 is a method according to Example 13, further comprising, at each of the one or more test devices, storing the copy of the test waveform as a local copy of the test waveform.

Example 16 is a method according to any of the previous Example methods, in which the test and measurement system includes a master controller, the method further comprising displaying the output from the one or more test devices on a user interface of the master controller.

Example 17 is a method according to any of the previous Example methods, further comprising sending a control command from the master controller to fewer than all of the one or more test devices.

Example 18 is a method according to any of the previous Example methods, further comprising accepting a selection of which of the one or more test devices to send the control command from a user.

Example 19 is a method according to any of the previous Example methods, in which the test waveform includes multiple segments, the method further comprising identifying a selected one of the multiple segments for routing to the one or more test devices.

Example 20 is a method according to any of the previous Example methods, further comprising sending synchronization information to the one or more test devices.

Example 21 is a method according to any of the previous Example methods, further comprising sending a stop command to the one or more test devices to simultaneously stop execution of the received command.

Example 22 is a method according to any of the previous Example methods, further comprising sending a restart command to the one or more test devices to restart execution of the received command for a pre-determined time, and then to stop execution of the received command.

Example 23 is a method according to any of the previous Example methods, further comprising sending a restart command to the one or more test devices to restart execution of the received command until a pre-determined event occurs, and then to stop execution of the received command.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure. Accordingly, the disclosure should not be limited except as by the appended claims.

We claim:

1. A test and measurement system, comprising:
a primary instrument including:
an input for receiving a test signal for measurement or analysis from a Device Under Test (DUT) and generating a test waveform from the test signal, and
a duplicator for sending a copy of the test waveform to one or more secondary instruments; and
the one or more secondary instruments each structured to access the copy of the test waveform for analysis, and each of the one or more secondary instruments including:
a receiver structured to receive a command related to measurement or analysis of the copy of the test waveform;
one or more processes for executing the received command; and
an output for sending results of the executed command to be displayed on a user interface that is separate from any user interface of the one or more secondary instruments.

2. The test and measurement system according to claim 1, further comprising a master controller coupled to the output of the one or more secondary instruments, and the master controller having a user interface with a window to display the output of each of the one or more secondary instruments.

3. The test and measurement system according to claim 2, in which the user interface of the master controller further includes an input for controlling the primary instrument and selected ones of the one or more secondary instruments.

4. The test and measurement system according to claim 1, in which each of the one or more secondary instruments is structured to execute its received command substantially simultaneously.

5. The test and measurement system according to claim 1, in which the test waveform includes multiple segments, and in which each of the one or more secondary instruments is structured to operate on the same of the multiple segments substantially simultaneously.

6. The test and measurement system according to claim 2, in which the master controller is structured to send synchronization information to the one or more secondary instruments.

7. The test and measurement system according to claim 1, in which at least one of the one or more secondary instruments operate as a virtual computer process.

8. The test and measurement system according to claim 1, in which each of the one or more secondary instruments lacks any input for receiving the test signal from the DUT.

9. The test and measurement system according to claim 1, in which each of the one or more secondary instruments is structured to, after receiving a stop command, stop execution and remain in a wait state.

10. The test and measurement system according to claim 9, in which each of the one or more secondary instruments is structured to simultaneously restart execution upon receipt of another command.

11. The test and measurement system according to claim 9, in which each of the one or more secondary instruments is structured to execute for a pre-defined time prior to stopping execution.

12. A test and measurement system, comprising:
a signal receiver in a primary instrument including an input for receiving a test signal for measurement or analysis from a Device Under Test (DUT) from which a test waveform is generated;
a master controller coupled to the signal receiver and structured to make a copy of the test waveform available to one or more secondary instruments; and
the one or more secondary instruments each structured to access the copy of the test waveform for analysis, and each of the one or more secondary instruments including:
a receiver structured to receive a command related to measurement or analysis of the copy of the test waveform from the master controller,
one or more processes for executing the received command, and
an output for sending results of the executed command to the master controller.

13. The test and measurement system according to claim 12, in which the master controller is structured to simultaneously display the output of each of the one or more secondary instruments.

14. A method of operating a test and measurement system, comprising:
receiving a test signal for measurement or analysis from a Device Under Test (DUT) at a first device;
generating a test waveform from the test signal;
selectively routing a copy of the test waveform to one or more test devices; and
at the one or more test devices,
receiving a command related to measurement or analysis of the copy of the test waveform,
executing the received command, and
sending an output of the executed command to a user interface that is separate from the one or more test devices.

15. The method of operating a test and measurement system according to claim 14, further comprising, at each of the one or more test devices, storing the copy of the test waveform as a local copy of the test waveform.

16. The method of operating a test and measurement system according to claim 14, in which the test and measurement system includes a master controller, the method further comprising displaying the output from the one or more test devices on a user interface of the master controller.

17. The method of operating a test and measurement system according to claim 16, further comprising sending a control command from the master controller to fewer than all of the one or more test devices.

18. The method of operating a test and measurement system according to claim 17, further comprising accepting a selection of which of the one or more test devices to send the control command from a user.

19. The method of operating a test and measurement system according to claim 14, in which the test waveform includes multiple segments, the method further comprising identifying a selected one of the multiple segments for routing to the one or more test devices.

20. The method of operating a test and measurement system according to claim 14, further comprising sending synchronization information to the one or more test devices.

21. The method of operating a test and measurement system according to claim 14, further comprising sending a stop command to the one or more test devices to simultaneously stop execution of the received command.

22. The method of operating a test and measurement system according to claim 21, further comprising sending a restart command to the one or more test devices to restart execution of the received command for a pre-determined time, and then to stop execution of the received command.

23. The method of operating a test and measurement system according to claim 21, further comprising sending a restart command to the one or more test devices to restart execution of the received command until a pre-determined event occurs, and then to stop execution of the received command.
